(19) United States
(12) Patent Application Publication
(10) Pub. No.: US 2024/0399465 A1
(43) Pub. Date: Dec. 5, 2024

(54) COATED TOOL PART AND COATING METHOD

(71) Applicant: Hartmetall-Werkzeugfabrik Paul Horn GmbH, Tuebingen (DE)

(72) Inventor: Jochen Kiepke, Tuebingen (DE)

(21) Appl. No.: 18/805,975

(22) Filed: Aug. 15, 2024

Related U.S. Application Data
(63) Continuation of application No. PCT/EP2023/062508, filed on May 10, 2023.

(30) Foreign Application Priority Data
May 31, 2022 (DE) 10 2022 113 731.7

(51) Int. Cl. B23B 27/14

(52) U.S. Cl. CPC B23B 27/148; B23B 2224/08; B23B 2228/105; B23B 2228/36

(57) ABSTRACT

A coated tool part of a machining tool, having a substrate coated with a wear layer and with a bonding layer disposed between the substrate and the wear layer. The wear layer and the bonding layer each have a plurality of sub-layers arranged one on top of another. Each sub-layer includes a first individual ply, a second individual ply, and a third individual ply, wherein the three individual plies in the plurality of sub-layers are arranged one on top of another in a regularly alternating sequence. The first individual ply includes Alₓ₁Me₁₋ₓ₁(N_{y1}C_{1-y1}). The second individual ply includes Alₓ₂Me₁₋ₓ₂(N_{y2}C_{1-y2}). The third individual ply includes Alₓ₃Me_{1-x3-z3}Si_{z3}(N_{y3}C_{1-y3}). A ply thickness of the third individual plies included in the bonding layer varies from sub-layer to sub-layer such that the ply thickness of the third individual ply in a sub-layer disposed further down, closer to the substrate.

### CROSS REFERENCE TO RELATED APPLICATIONS

This application is a continuation of international patent application PCT/EP2023/062508, filed on May 10, 2023 designating the U.S., which international patent application has been published in German language and claims priority from German patent application DE 10 2022 113 731.7, filed on May 31, 2022. The entire contents of these priority applications are incorporated herein by reference.

### FIELD

This disclosure relates to a coated tool part of a machining tool. This disclosure further relates to a method of coating a tool part of a machining tool.

### BACKGROUND

The tool part and the machining tool may, for example, be respectively a tool part and tool that are used in the metalworking industry. In principle, however, such tools may also be used for processing of other materials, for example glass, plastic, etc.

Machining tools are, for example, turning tools, milling tools, drilling tools, power skiving tools, etc. The herein presented coated tool part is part of such a machining tool which is either configured as a separate part, for example as a cutting insert, or is a part of the tool integrated with a tool holder or tool shaft.

The coated tool part is preferably made from cemented carbide, cermet, polycrystalline cubic boron nitride, polycrystalline diamond, cutting ceramic or high-speed steel. The aforementioned materials thus serve as substrates for the coating.

Although the aforementioned materials already have very good machining properties, since they have very high hardness, wear resistance and fracture resistance, tool parts of machining tools or the entire machining tool are increasingly being coated in order to optimize machining properties. Such coatings give the tool part or tool optimal protection from dynamic stresses at high cutting speeds and with poor cooling, if any. It is thus possible to distinctly increase the service lives of such machining tools with the aid of suitable coatings.

The prior art already discloses a plurality of different coatings. In this regard, reference is made merely by way of example to EP 2 310 594, EP 1 422 311 and EP 2 336 382. The three aforementioned publications disclose various AlCrSiN coatings. The coating known from EP 1 422 311 is, for example, an arc-PVD coating. Such arc-PVD coatings have a high defect density, which frequently leads to premature material failure. DC-sputtered layers, by contrast, are frequently too soft and/or have inadequate layer adhesion owing to comparatively low ionization.

Al-containing layers very frequently have the problem that they form a hexagonal phase even in the case of low Al contents (hexagonal crystal structure), which reduces the hardness and wear resistance of the coating. What would be more desirable, by contrast, would be Al-containing coatings with a cubic crystal structure. However, the latter is barely achievable in the case of relatively high Al contents.

### SUMMARY

It is an object to provide a coating for a tool part of a machining tool that has a comparatively high Al content but nevertheless has a cubic crystal structure and therefore has very high hardness and high wear resistance.

According to a first aspect, a coated tool part is provided that comprises a substrate coated with a wear layer and with a bonding layer disposed between the substrate and the wear layer, wherein the wear layer and the bonding layer each have a plurality of sub-layers arranged one on top of another, wherein each sub-layer comprises a first individual ply, a second individual ply and a third individual ply, wherein the three individual plies in the plurality of sub-layers are arranged one on top of another in a regularly alternating sequence, wherein the first individual ply comprises Alx1Me1-x1(Ny1C1-y1), the second individual ply comprises Alx2Me1-x2(Ny2C1-y2), and the third individual ply comprises Alx3Me1-x3-z3Siz3(Ny3C1-y3), where 0≤x1≤0.55 and x1<x2, x1<x3 and 0≤y1, y2, y3≤1, where Me includes at least one of the following elements: Sc, Y, La, Ti, Zr, Hf, V, Nb, Ta, Cr, Mo, W, wherein a ply thickness of the third individual plies included in the bonding layer varies from sub-layer to sub-layer such that the ply thickness of the third individual ply in a sub-layer disposed further down, closer to the substrate, is lower than the ply thickness of the third individual ply in a sub-layer disposed further up, further away from the substrate, and wherein a ply thickness of the third individual plies included in the wear layer is essentially constant from sub-layer to sub-layer or at least varies less significantly from sub-layer to sub-layer than in the bonding layer.

According to a second aspect, a tool for machining a workpiece is provided, wherein the tool includes a coated tool part, the coated tool part comprising a substrate, a wear layer, and a bonding layer. The substrate being coated with the wear layer and the bonding layer. The bonding layer being disposed between the substrate and the wear layer. The wear layer and the bonding layer each comprising a plurality of sub-layers arranged one on top of another. Each of the plurality of sub-layers comprising a first individual ply, a second individual ply and a third individual ply, wherein the three individual plies in the plurality of sub-layers are arranged one on top of another in a regularly alternating sequence. The first individual ply comprising Alx1Me1x1(Ny1C1-y1), the second individual ply comprising Alx2Me1-x2(Ny2C1-y2), and the third individual ply comprising Alx3Me1x3-z3Siz3(Ny3C1-y3), where 0≤x1≤0.55 and x1<x2, x1<x3 and 0≤y1, y2, y3≤1, and where Me includes at least one of the following elements: Sc, Y, La, Ti, Zr, Hf, V, Nb, Ta, Cr, Mo, W. A ply thickness of the third individual plies included in the bonding layer varies from sub-layer to sub-layer in such a way that the ply thickness of the third individual ply in a first one of the plurality of sub-layers is smaller than the ply thickness of the third individual ply in a second one of the plurality of sub-layers, the first one of the plurality of sub-layers being arranged closer to the substrate than the second one of the plurality of sub-layers. The ply thickness of the third individual plies included in the wear layer is constant from sub-layer to sub-layer or at least varies less from sub-layer to sub-layer than in the bonding layer.

According to a third aspect, a method is provided, comprising:
providing the tool part that acts as substrate;
coating the substrate with a bonding layer;
coating the substrate coated with the bonding layer with a wear layer;
   wherein the coating of the substrate with the bonding layer and the coating of the substrate coated with the bonding layer each comprise a deposition of a plurality of sub-layers arranged one on top of another, wherein each sub-layer comprises a first individual ply, a second individual ply and a third individual ply, wherein the three individual plies in the plurality of sub-layers are arranged one on top of another in a regularly alternating sequence, wherein the first individual ply comprises Alₓ₁Me₁₋ₓ₁(N_{y1}C_{1-y1}), the second individual ply comprises Alₓ₂Me₁₋ₓ₂(N_{y2}C_{1-y2}), and the third individual ply comprises Alₓ₃Me_{1-x3-z3}Si(Ny₃C_{1-y3}), where 0≤x1≤0.55 and x1<x2, x1<x3 and 0≤y1, y2, y3≤1, where Me includes at least one of the following elements: Sc, Y, La, Ti, Zr, Hf, V, Nb, Ta, Cr, Mo, W, wherein a ply thickness of the third individual plies included in the bonding layer varies from sub-layer to sub-layer such that the ply thickness of the third individual ply in a sub-layer disposed further down, closer to the substrate, is lower than the ply thickness of the third individual ply in a sub-layer disposed further up, further away from the substrate, and wherein a ply thickness of the third individual plies included in the wear layer is essentially constant from sub-layer to sub-layer or at least varies less significantly from sub-layer to sub-layer than in the bonding layer.

The coating thus comprises a bonding layer, and a wear layer disposed on top. Each layer consists of a plurality of sub-layers, with each sub-layer having at least three different individual plies, referred to in the present context as “first individual ply”, “second individual ply” and “third individual ply”. In principle, each sub-layer may also have more than three individual plies.

The three individual plies mentioned in the different sub-layers have different material compositions (see below for details). The three individual plies mentioned in the plurality of sub-layers, both in the bonding layer and in the wear layer, are arranged one on top of another in a regularly alternating sequence. The sequence of the individual plies in the bonding layer may, but need not necessarily, be the same sequence as in the wear layer. It should additionally be mentioned that the nomenclature “first, second and third individual ply” used in the present context, rather than implying an obligatory sequence, is merely intended to differentiate between the three individual plies.

If the first individual ply is referred to by way of simplification as “1”, the second individual ply as “2” and the third individual ply as “3”, the following sequences, for example, are possible in the bonding layer and/or the wear layer: 123123123 . . . or 213213213 . . . or 321321321 . . . or 123412341234 . . . etc., in which case “4” would represent one or more further individual plies per sub-layer.

The first individual ply comprises Alx1Me1-x1(Ny1C1-y1) where: 0≤x1≤0.55 and 0≤y1≤1 and Me includes at least one of the following elements: Sc, Y, La, Ti, Zr, Hf, V, Nb, Ta, Cr, Mo, W. Since x1 may also be 0, this means that the first individual ply need not necessarily include aluminum but may also include “only” one of the aforementioned metals Me. Preferably, however, the first individual ply includes both aluminum and one of these metals. However, the Al is comparatively small. Since y1 may vary between 0 and 1, the first individual ply may be a nitride, a carbide or a carbonitride.

The situation is also similar in respect of the compositions of the second and third individual plies, where the second individual ply comprises Alx2Me1-x2 and, because of the fact that x1 is less than x2, inevitably has a higher Al content than the first individual ply. Because 0≤y2≤1, it is also possible for the second individual ply to comprise a nitride, a carbide or a carbonitride.

In the third individual ply Alx3Me1-x3-z3Siz3(Ny3C1-y3), the substance mixture, in addition to aluminum and the further metal, also includes Si. This substance mixture too may take the form of a nitride, carbide or carbonitride (0≤y3≤1). The Al content of the third individual ply is greater than the Al content of the first individual ply, but not necessarily greater than the Al content of the second individual ply.

It should be pointed out that the molar proportions of the three individual plies specified herein are each reported in absolute terms as decimal numbers, such that, for example, a molar proportion of 0.55 corresponds to a molar proportion in atom percent of 55% (55 at %).

The specified material compositions of the three individual plies and the alternating sequence thereof one on top of another offer various technical advantages. The first individual ply has a comparatively low Al content (<55 at %). It may also have an entirely Al-free configuration. In combination with one or more of the abovementioned metals Me, the substance mixture included in the first individual ply has a cubic crystal structure. The inclusion of cubic nitrides (e.g. CrN, TiN . . . ) or cubic carbides (e.g. TiC, ZrC . . . ) can generate a cubic solid solution which, by comparison with pure aluminum nitride or aluminum carbide, which typically has a hexagonal crystal structure, has much higher hardness and high wear resistance.

The same principle of inclusion of cubic nitrides or cubic carbides is also applicable to the second individual ply. Because of the higher Al content in the second individual ply, the substance mixture present therein, however, would actually have a hexagonal crystal structure. Because of the alternating sequence of the individual plies mentioned, however, the second individual ply is cubically “stabilized” by the first individual ply, such that this ultimately also has a cubic crystal structure. Thus, the second individual plies also contribute advantageously to the higher hardness and higher wear resistance. The comparatively high Al content in the second individual ply leads not only to the high hardness but also to a high oxidation resistance.

The silicon nitride or silicon carbide included in the third individual ply also increases the hardness of the coating. But silicon nitride or silicon carbide normally likewise promote the formation of a hexagonal crystal structure. However, the hexagonal crystal structure of the third individual ply is likewise suppressed because of the cubic crystal structure of the first individual ply. Thus, the actually hexagonal crystal structure of the third individual ply is also “cubically stabilized” because of the first individual ply.

What this means in summary is that the hexagonal phase that normally occurs in the second and third individual plies because of the material compositions is suppressed by the application of the low-Al first individual plies that are respectively disposed in between and include cubic nitrides or cubic carbides. The cubic crystal structure in the first individual plies thus ultimately also leads to cubic crystal structures in the second and third individual plies. This has been found to be extremely advantageous.

A further feature of the coating is that the ply thickness of the third individual plies varies from sub-layer to sub-layer in the bonding layer. The ply thickness of the third individual plies preferably increases from the bottom upwards. However, the increase need not be exactly constant, which can barely be guaranteed in any case for process-related reasons. What is important is that the ply thickness of the third individual plies at least tends to increase from the bottom upwards, meaning that the ply thickness of a third individual ply in at least one sub-layer disposed further down, closer to the substrate, is lower than the layer thickness of the third individual ply in at least one sub-layer disposed further up, further away from the substrate.

In the wear layer, the ply thickness of the third individual plies varies less significantly than in the bonding layer. The ply thickness of the third individual plies included in the wear layer is preferably essentially constant (constant with processing-related variances).

There is thus no “hard” transition between the individual plies of the bonding layer and the individual plies of the wear layer. There is instead a kind of Si gradient that rises from the bottom upward within the bonding layer. As a result, the entire coating is Si-containing and hence harder than a comparable coating with an Si-free bonding layer.

The coating can especially be produced by high-energy impulse magnetron sputtering (HiPIMS). Production by HiPIMS with very high pulse power produces very dense and low-defect layers.

In a refinement, 0.55≤x2≤0.7 and 0.4≤x3≤0.7. In other words, the Al content in the second individual plies preferably varies between 0.55 and 0.7, while the Al content in the third individual plies preferably varies between 0.4 and 0.7. These Al contents have been found to be advantageous in the tests conducted by the applicant.

In a further refinement, the following applies: 0.3≤x1≤0.55 and 0.55≤x2≤0.65 and 0.5≤x3≤0.65.

In a further refinement, the following is applicable to the third individual plies: 0.01≤z3≤0.15. The Si content thus preferably varies between 1% and 15%.

It has been found to be particularly advantageous to include Cr as metal (Me) in the three individual plies. Particularly good test results were achieved by the inclusion of chromium nitride in the three individual plies (Me=Cr, y1=1, y2=1 and y3=1).

As already mentioned, it is preferable that the ply thickness of the third individual plies included in the bonding layer increases monotonously from sub-layer to sub-layer with increasing distance from the substrate. This leads to a “perfect” gradient progression of the Si content in the bonding layer. Because of the production-related rotation of the tool part during coating, however, there may be variances in the individual ply thicknesses, and therefore the increase can in practice be described merely as “essentially constant” or at least as “having an increasing trend”.

The ply thicknesses of the first, second and third individual plies in the wear layer are preferably constant or at least essentially constant/similar. In a preferred refinement, the following is respectively applicable to a ply thickness twear of the first, second and third individual plies included in the wear layer: 1 nm≤twear≤200 nm, preferably 1 nm≤twear≤30 nm, more preferably 2 nm≤twear≤25 nm.

In a depth direction, in which the sub-layers are arranged one on top of another, this leads to more than three sub-layers per micrometer respectively in the bonding layer and in the wear layer, preferably to more than 10 sub-layers per micrometer, more preferably to more than 20 sub-layers per micrometer.

The layer thickness of the overall bonding layer is preferably less than the layer thickness of the wear layer.

It is evident that the features referred to above and those yet to be explained below can be used not only in the respective combination indicated, but also in other combinations or individually, without departing from the spirit and scope of the present disclosure. It will also be apparent that the aforementioned features and the features defined in the claims for the coated tool part also relate in the same or an equivalent manner to the presented tool for machining and the presented method.

### BRIEF DESCRIPTION OF THE DRAWINGS

FIG. 1 shows a schematic diagram of a coated tool part according to an embodiment;

FIG. 2 shows a schematic diagram for illustration of the layer structure of a coating according to an embodiment;

FIG. 3 shows a schematic diagram of a test setup for production of a coating according to an embodiment;

FIG. 4 shows a diagram with test results;

FIG. 5 shows a light microscope image of a crater-ground sample of a substrate coated with the coating;

FIG. 6 shows an SEM image of a substrate coated with the coating;

FIG. 7 shows a result of an XRD analysis; and

FIG. 8 shows a table of experimental results for various coating variants.

### DETAILED DESCRIPTION

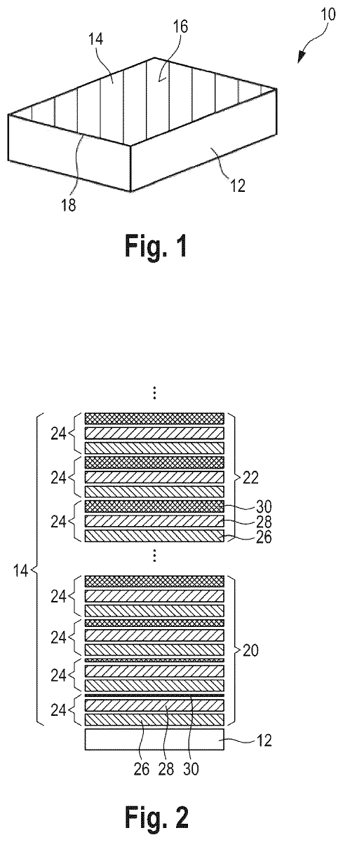

FIG. 1 shows, in purely schematic form, a coated tool part. The coated tool part is denoted in its entirety by reference numeral 10.

The coated tool part 10 may, for example, be a cutting insert. The coated tool part 10, in the present embodiment, comprises a substrate 12 made of cemented carbide that has been coated on its topside with a coating 14. It is of course also possible for the whole surface of the tool part 10 to have been coated.

In the present case, the coated surface may, for example, be the rake face 16 of a cutting insert that comprises one or more cutting edges 18.

FIG. 2 shows, in a schematic manner, the layer structure of the coating 14. The coating 14 is divided into a bonding layer 20 and a wear layer 22. The bonding layer 20 bonded directly to the substrate 12. The wear layer 22 has been applied to the top side of the bonding layer 20.

The bonding layer 20 and also the wear layer 22 each have a plurality of sub-layers 24. These sub-layers 24 in the present case each consist of three individual plies 26, 28, 30. In other embodiments (not shown here), there may also be further individual plies for each sub-layer 24.

The individual plies 26, 28, 30, referred to in the present context as first individual plies 26, second individual plies 28 and third individual plies 30, each have different material compositions, where each of the first individual plies 26, each of the second individual plies 28 and each of the third individual plies 30 have the same material composition. The three individual plies are arranged one on top of another in alternating sequence; the sequence 123123123 . . . has been chosen in the present case.

The first individual plies 26 and the second individual plies 28 in all sub-layers 24 preferably have the same thickness. However, the ply thickness of the third individual plies 30 varies in the bonding layer 20, whereas it is preferably the same size or the same thickness (i.e. does not vary) in the sub-layers 24 of the wear layer 22. In the bonding layer 20, the ply thickness of the third individual plies 30 at least has a tendency to increase from the bottom upward, i.e. proceeding from the substrate 12 up to the transition to the wear layer 22. It is particularly preferable when the ply thickness of the third individual plies 30 in the bonding layer 20 increases essentially constantly from sub-layer 24 to sub-layer 24. An “essentially constant” increase means a constant increase with relatively small process-related variances.

The thickness of the overall coating 14 is preferably in the range of 1-10 μm. The layer thickness of the bonding layer 20 is preferably less than the layer thickness of the wear layer 22. More preferably, the bonding layer 20 has a proportion of 10-30% of the total layer thickness of the coating 14.

The first and second individual plies 26, 28 preferably have a ply thickness of 1-30 nm. The ply thickness of the third individual plies 30 varies, as already mentioned, in the bonding layer 20. It preferably rises uniformly within the bonding layer 20 from sub-layer 24 to sub-layer 24 from the bottom upward.

The first individual plies 26 comprise the following substance mixture: Alx1Me1-x1(Ny1C1-y1). The second individual plies 28 comprise the following substance mixture: Alx2Me1-x2(Ny2C1-y2). The third individual plies 30 comprise the following substance mixture: Alx3Me1-x3-z3Siz3(Ny3C1-y3). The parameters x1, x2, x3, y1, y2 and y3 are subject to the following conditions: 0≤x1≤0.55, x1<x2, x1<x3, 0≤y1≤1, 0≤y2≤1 and 0≤y3≤1. The metal Me includes at least one of the following elements: Sc, Y, La, Ti, Zr, Hf, V, Nb, Ta, Cr, Mo and W.

The low Al content within the first individual plies 26 and the addition of cubic nitrides or cubic carbides (MeN or MeC), in the second and third individual plies 28, 30 as well, leads to cubic crystal structures, as shown by the tests conducted by the applicant. The constantly rising Si content in the third individual plies 30 of the bonding layer 20 already leads to a bonding layer 20 having high hardness that has optimal adhesion to the substrate 12. In addition, as a result of this rising progression in the proportion of Si within the bonding layer 20, there is no abrupt transition between the bonding layer 20 and the wear layer 22.

The first individual plies 26 that are respectively arranged in between thus have the effect that the second and third individual plies 28, 30 as well, which would have a hexagonal crystal structure on the basis of their material composition (high Al content in the second individual plies 28 and high Al content and additional Si content in the third individual plies 30), likewise have a cubic crystal structure.

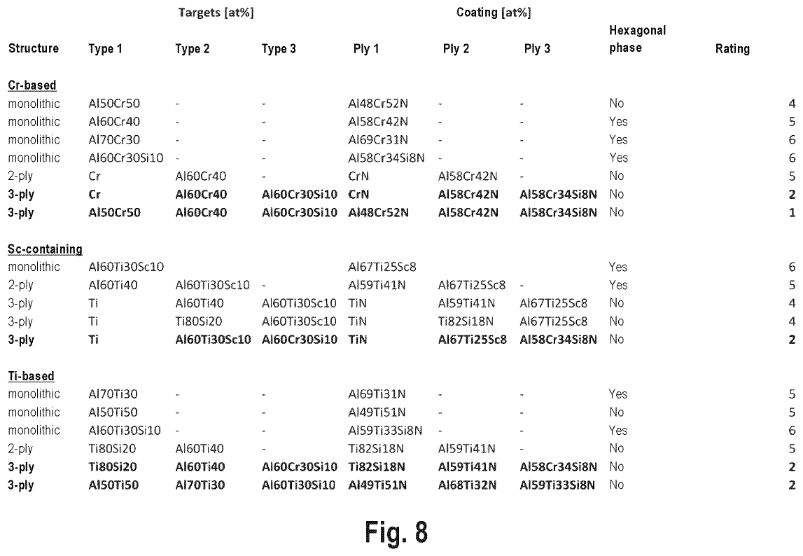

Experiments conducted by the applicant in which the material compositions of the three individual plies 26, 28, 30 were varied showed that sub-layers 24 of 3-ply configuration are distinctly advantageous both in relation to hardness and in relation to wear resistance. FIG. 8 summarizes some of these experimental results. For the various layer structures of the sub-layers 24, the material composition of each of the individual plies 26, 28, 30 (referred to here as “ply 1”, “ply 2” and “ply 3”) is shown. In addition, the first column in each case gives the basic structure of the sub-layers 24 (monolithic, 2-ply or 3-ply). Additionally stated is whether or not a hexagonal crystal structure/phase arises. In the last column, the individual layers evaluated were assessed qualitatively, using 1 for very good, 2 for good, 3 for satisfactory, 4 for adequate, 5 for inadequate and 6 for unsatisfactory. Unlike before, the molar proportions of the material compositions shown in FIG. 8 are given as percentages in at % and not in absolute decimal form. Nevertheless, these are again given hereinafter as the absolute molar proportion in decimal form.

Advantageous Al contents in the first individual ply 26 have especially been found to be Al contents of 0≤x1≤0.55. In addition, preferred Al contents in the second individual plies 28 are 0.55≤x2≤0.65, and in the third individual plies 30 are 0.5≤x3≤0.65. Si contents of 0.01≤z3≤0.15 have been found to be advisable/advantageous for the third individual plies 30. The following material compositions were found to be particularly advantageous for the three individual plies 26, 28, 30, each reported as (material composition of first individual ply 26, material composition of second individual ply 28, material composition of third individual ply 30): (CrN, Al0.58Cr0.42N, Al0.58Cr0.34Si0.08N); (Al0.48Cr0.52N, Al0.58Cr0.42N, Al0.58Cr0.34Si0.08N), (TiN, Al0.67Ti0.25Sc0.08, Al0.58Cr0.34Si0.08N), (Ti0.82Si0.18N, Al0.59Ti0.41N, Al0.58Cr0.34Si0.08N), (Al0.49Ti0.51N, Al0.68Ti0.32N, Al0.59Ti0.33Si0.08N).

FIG. 8 shows merely experimental results for nitrides, although further results obtained by the applicant that are not shown here showed that various carbides having similar properties and molar proportions of Al and Me would also be usable in an equivalent manner.

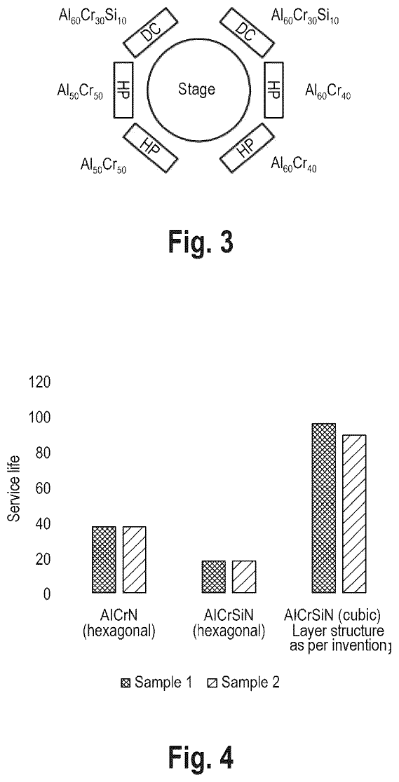

FIG. 3 shows, in schematic form, an experimental setup as used for production of the Cr-based coating 14 with the material composition (Al0.48Cr0.52N, Al0.58Cr0.42N, Al0.58Cr0.34Si0.08N). For this purpose, a PVD coating apparatus was used, which assists the sputtering by the HiPIMS method. In the present case, the applicant used the CC800-HiPIMS from CemeCon AG. The coating apparatus used comprises six cathodes, with four cathodes operated in HiPIMS mode and two cathodes in DC mode. The Si-free targets that are used for deposition of the first and second individual plies 26, 28 are operated in HiPIMS mode (identified in FIG. 3 as “HP”); the Si-containing targets that are used for deposition of the third individual plies 30 are operated in DC mode (identified in FIG. 3 as “DC”). This is therefore a hybrid process overall.

For the coating process, the cleaned tools 10 and substrates 12 are charged in the coating apparatus. According to their diameter, the charging is effected in single, double, triple or quadruple rotation, such that all functional surfaces can be coated.

In order to prepare for the coating process, the coating apparatus generates a high vacuum in the chamber and the radiative heaters present therein heat the tools to about 500° C. The plasma etching process that follows cleans the tool surface. For this purpose, a pressure of 200 to 500 mPa is established in the coating space with the aid of noble gas and a plasma is generated. A negative voltage of more than 100 V accelerates the noble gas ions onto the tool surface, which removes impurities there.

In the last step before the coating, brief sputtering of the targets cleans the target surface. For this purpose, with the aid of noble gases, a pressure of more than 1000 mPa is generated, and the application of a negative voltage to the targets starts the sputtering process. During this target cleaning operation, closed shutters protect the tools from application of material.

This may be followed by the actual coating of the tools or tool parts 10 or substrates 12. For this purpose, with the aid of noble gases, a pressure of 300 to 600 mPa is generated, and then the reactive gas, nitrogen and/or acetylene, is admitted until there is a total pressure of 630 to 1000 mPa. In order that a tight layer structure is formed, up to four of the cathodes used are not operated with a continuous voltage, but rather supplied with voltage pulses and hence operated in what is called HiPIMS mode. These HiPIMS pulses have a length of 10 to 200 μs, preferably 20 to 100 μs, and are generated 1000 to 8000 times per second. The supplying of the tools with a negative voltage of 40 to 100 V accelerates the metal ions thus generated onto the tools. In order to start the sputtering process, the cathodes with the silicon-free targets are very quickly supplied with a voltage, such that there is an average power of 6000 to 12 000 W across the cathodes. The voltage across the silicon-containing targets, by contrast, is increased over a period of 10 to 20 minutes, such that the average sputtering power of these targets rises gradually and continuously and hence the thickness of the third individual plies 30 of the bonding layer 20 rises, resulting in the silicon gradient described. After this gradient has been deposited, all targets are operated at constant power. The rotation of the tools during the coating process gives rise to the nanostructured coating 14.

After conclusion of the coating process, the chamber cools down to below 200° C. before being ventilated, such that the now coated tools can be removed.

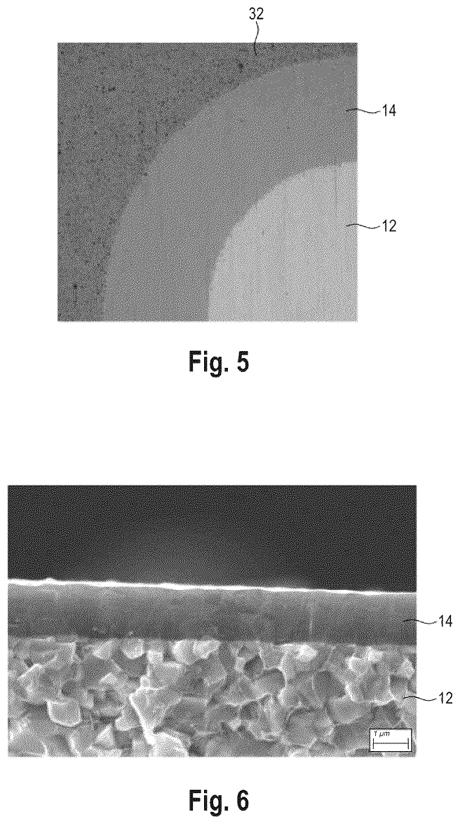

The material compositions of the targets shown in FIG. 3 correspond to the material compositions shown in FIG. 8 in the last line of the Cr-based substance mixtures. The coating achieved thereby (Al0.48Cr0.52N, Al0.58Cr0.42N, Al0.58Cr0.34Si0.08N) gave by far the best results, especially as shown by the evaluated service lives of the coated tool parts. In FIG. 4, this is shown by a service life evaluation of various coatings, with comparison of the inventive manner of coating (shown far right in FIG. 4) of an AlCrN coating with hexagonal crystal structure and of an AlCrSiN layer with hexagonal crystal structure. As evident from this comparison, it was possible with the coating to achieve service lives that were twice as long as those with hexagonal AlCrN layers and hexagonal AlCrSiN layers. FIGS. 5 and 6 show the inventive AlCrSiN coating in a light microscope image and an SEM image. These show, in particular, the substrate 12 and the coating 14 adhering thereto. In FIG. 5, it is possible to see the sub-layers 24. Moreover, because of the crater-ground sample, the surface 32 of the coating 14 is apparent.

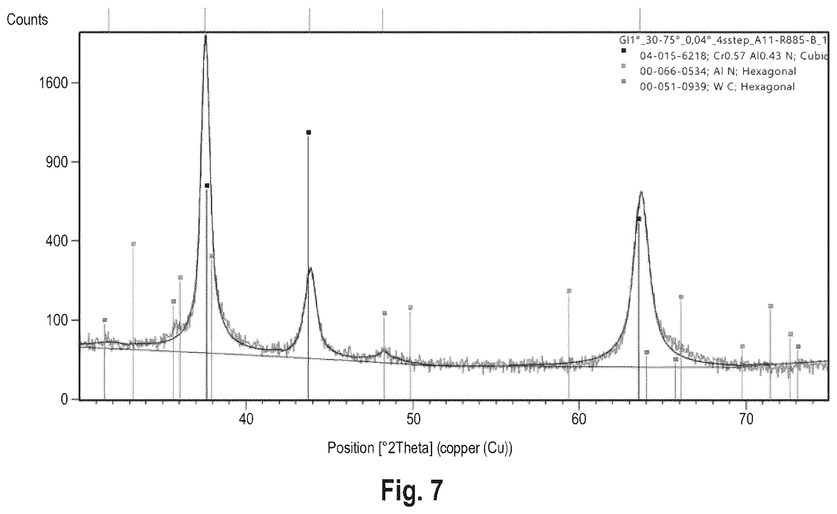

An XRD analysis conducted by the applicant, the result of which is shown in FIG. 7, again supports the fact that no hexagonal phase occurs as crystal structure for the inventive coating 14, but merely a cubic phase. Further XRD analyses gave compressive stresses of >2.5 GPa. Instrumented indentation tests gave a hardness of >33 GPa and a ratio of indentation hardness HIT to elastic indentation modulus EIT of: HIT3/EIT2>0.15 (usually even greater than 0.2).

The result was thus extremely good material properties of the inventive coating 14.

It is to be understood that the foregoing is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “for example,” “e.g.,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

What is claimed is:

1. A coated tool part of a machining tool, comprising:
a substrate;
a wear layer; and
a bonding layer,
wherein the substrate is coated with the wear layer and the bonding layer,
wherein the bonding layer is disposed between the substrate and the wear layer,
wherein the wear layer and the bonding layer each comprises a plurality of sub-layers arranged one on top of another,
wherein each of the plurality of sub-layers comprises a first individual ply, a second individual ply, and a third individual ply, wherein the three individual plies in the plurality of sub-layers are arranged one on top of another in a regularly alternating sequence,
wherein the first individual ply comprises Alₓ₁Me₁₋ₓ₁(N_{y1}C_{1-y1}), the second individual ply comprises Alₓ₂Me₁₋ₓ₂(N_{y2}C_{1-y2}), and the third individual ply comprises Alx₃Me_{1-x3-z3}Si_{z3}(Ny₃C_{1-y3}), where 0≤x1≤0.55 and x1<x2, x1<x3 and 0≤y1, y2, y3≤1, and where Me includes at least one of the following elements: Sc, Y, La, Ti, Zr, Hf, V, Nb, Ta, Cr, Mo, and W,
wherein a ply thickness of the third individual plies included in the bonding layer varies from sub-layer to sub-layer in such a way that the ply thickness of the third individual ply in a first one of the plurality of sub-layers is smaller than the ply thickness of the third individual ply in a second one of the plurality of sub-layers, the first one of the plurality of sub-layers being arranged closer to the substrate than the second one of the plurality of sub-layers, and
wherein the ply thickness of the third individual plies included in the wear layer is constant from sub-layer to sub-layer or at least varies less from sub-layer to sub-layer than in the bonding layer.

2. The coated tool part according to claim 1, wherein the Alₓ₁Me₁₋ₓ₁(N_{y1}C_{1-y1}) included in the first individual ply, the Alₓ₂Me₁₋ₓ₂(N_{y2}C_{1-y2}) included in the second individual ply, and the Alₓ₃Me_{1-x3-z3}Si_{z3}(Ny₃C_{1-y3}) included in the third individual ply each have a cubic crystal structure.

3. The coated tool part according to claim 1, wherein 0.55≤x2≤0.7 and 0.4≤x3≤0.7.

4. The coated tool part according to claim 1, wherein 0≤x1≤0.55 and 0.55≤x2≤0.65 and 0.5≤x3≤0.65.

5. The coated tool part according to claim 1, wherein 0.01≤z3≤0.15.

6. The coated tool part according to claim 1, wherein Me includes Cr.

7. The coated tool part according to claim 1, wherein y1=1, y2=1 and y3=1.

8. The coated tool part according to claim 1, wherein the ply thickness of the third individual plies included in the bonding layer increases monotonously from sub-layer to sub-layer with increasing distance from the substrate.

9. The coated tool part according to claim 1, wherein the following applies for a first ply thickness t_{wear1} of each of the first individual plies included in the wear layer, a second ply thickness t_{wear2} of each of the second individual plies included in the wear layer, and a third ply thickness t_{wear3} of each of the third individual plies included in the wear layer: 1 nm≤t_{wear1}, t_{wear2}, t_{wear3}≤200 nm.

10. The coated tool part according to claim 1, wherein the following applies for a first ply thickness t_{wear1} of each of the first individual plies included in the wear layer, a second ply thickness t_{wear2} of each of the second individual plies included in the wear layer, and a third ply thickness t_{wear3} of each of the third individual plies included in the wear layer: 1 nm≤t_{wear1}, t_{wear2}, t_{wear3}≤30 nm.

11. The coated tool part according to claim 1, wherein the following applies for a first ply thickness t_{wear1} of each of the first individual plies included in the wear layer, a second ply thickness t_{wear2} of each of the second individual plies included in the wear layer, and a third ply thickness t_{wear3} of each of the third individual plies included in the wear layer 5 nm≤t_{wear1}, t_{wear2}, t_{wear3}≤25 nm.

12. The coated tool part according to claim 1, wherein, in a depth direction, in which the sub-layers are arranged one on top of another, in the bonding layer and in the wear layer, there are more than 3 sub-layers per 1 μm arranged one on top of another.

13. The coated tool part according to claim 1, wherein, in a depth direction, in which the sub-layers are arranged one on top of another, in the bonding layer and in the wear layer, there are more than 10 sub-layers per 1 μm.

14. The coated tool part according to claim 1, wherein, in a depth direction, in which the sub-layers are arranged one on top of another, in the bonding layer and in the wear layer, there are more than 20 sub-layers per 1 μm.

15. The coated tool part according to claim 1, wherein a layer thickness of the bonding layer is smaller than a layer thickness of the wear layer.

16. The coated tool part according to claim 1, wherein the substrate comprises at least one selected from the group consisting of a cemented carbide, a cermet, a polycrystalline cubic boron nitride, a polycrystalline diamond, a cutting ceramic, and a high-speed steel.

17. A tool for machining a workpiece, wherein the tool includes a coated tool part, the coated tool part comprising:
a substrate;
a wear layer; and
a bonding layer,
wherein the substrate is coated with the wear layer and the bonding layer,
wherein the bonding layer is disposed between the substrate and the wear layer,
wherein the wear layer and the bonding layer each comprises a plurality of sub-layers arranged one on top of another,
each of the plurality of sub-layers comprises a first individual ply, a second individual ply, and a third individual ply, wherein the three individual plies in the plurality of sub-layers are arranged one on top of another in a regularly alternating sequence,
wherein the first individual ply comprises Alₓ₁Me₁₋ₓ₁(N_{y1}C_{1-y1}), the second individual ply comprises Alₓ₂Me₁₋ₓ₂(N_{y2}C_{1-y2}), and the third individual ply comprises Alₓ₃Me_{1-x3-z3}Si_{z3}(Ny₃C_{1-y3}), where 0≤x1≤0.55 and x1<x2, x1<x3 and 0≤y1, y2, y3≤1, and where Me includes at least one of the following elements: Sc, Y, La, Ti, Zr, Hf, V, Nb, Ta, Cr, Mo, and W,
wherein a ply thickness of the third individual plies included in the bonding layer varies from sub-layer to sub-layer in such a way that the ply thickness of the third individual ply in a first one of the plurality of sub-layers is smaller than the ply thickness of the third individual ply in a second one of the plurality of sub-layers, the first one of the plurality of sub-layers being arranged closer to the substrate than the second one of the plurality of sub-layers, and
wherein the ply thickness of the third individual plies included in the wear layer is constant from sub-layer to sub-layer or at least varies less from sub-layer to sub-layer than in the bonding layer.

18. A method, comprising:
providing a tool part having a substrate;
coating the substrate with a bonding layer; and
coating the substrate coated with the bonding layer with a wear layer,
wherein the coating of the substrate with the bonding layer and the coating of the substrate coated with the wear layer each comprise a deposition of a plurality of sub-layers arranged one on top of another,
wherein each of the plurality of sub-layers comprises a first individual ply, a second individual ply, and a third individual ply, wherein the three individual plies in the plurality of sub-layers are arranged one on top of another in a regularly alternating sequence,
wherein the first individual ply comprises Alₓ₁Me₁₋ₓ₁(N_{y1}C_{1-y1}), the second individual ply comprises Alₓ₂Me₁₋ₓ₂(N_{y2}C_{1-y2}), and the third individual ply comprises Alₓ₃Me_{1-x3-z3}Si_{z3}(Ny₃C_{1-y3}), where 0≤x1≤0.55 and x1<x2, x1<x3 and 0≤y1, y2, y3≤1, where Me includes at least one of the following elements: Sc, Y, La, Ti, Zr, Hf, V, Nb, Ta, Cr, Mo, W,
wherein a ply thickness of the third individual plies included in the bonding layer varies from sub-layer to sub-layer in such a way that the ply thickness of the third individual ply in a first one of the plurality of sub-layers is smaller than the ply thickness of the third individual ply in a second one of the plurality of sub-layers, the first one of the plurality of sub-layers being arranged closer to the substrate than the second one of the plurality of sub-layers, and
wherein the ply thickness of the third individual plies included in the wear layer is constant from sub-layer to sub-layer or at least varies less from sub-layer to sub-layer than in the bonding layer.
